(19) United States
(12) Patent Application Publication
(10) Pub. No.: US 2024/0371874 A1
(43) Pub. Date: Nov. 7, 2024

(54) Nanostructure Comprising Nanosheet or Nanowire Transistors

(71) Applicants: IMEC VZW, Leuven (BE); HUAWEI TECHNOLOGIES CO., LTD., Shenzhen, Guangdong (CN)

(72) Inventors: Amita Rawat, Mumbai (IN); Hao Wu, Chengdu (CN); Geert Hellings, Halle (BE); Krishna Kumar Bhuwalka, Heverlee (BE)

(21) Appl. No.: 18/688,594

(22) PCT Filed: Sep. 3, 2021
(86) PCT No.: PCT/EP2021/074400

§ 371 Date: Mar. 1, 2024

(51) Int. Cl. H01L 27/092; H01L 29/06; H01L 29/16; H01L 29/417; H01L 29/423; H01L 29/775; H01L 29/786

(52) U.S. Cl. CPC H01L 27/0922; H01L 29/0653; H01L 29/16; H01L 29/41775; H01L 29/0673; H01L 29/42392; H01L 29/775; H01L 29/78696

(57) ABSTRACT

A nanostructure according to the present disclosure comprises a pair of nanosheet or nanowire transistors configured to conduct charge by carriers of opposite polarity (such as n and p type carriers), wherein one of the pair of transistors is provided with inner spacers and the other is not provided with inner spacers. Depending on the type of charge carrier, the omission of the inner spacers may improve the admittance of the device. This is demonstrated in an example embodiment comprising a Si-channel PMOS nanosheet transistor. Conversely, in a Si-channel NMOS nanosheet transistor, the omission of the inner spacers has a negative effect on the parasitic capacitance that outweighs some of the benefits of the inner spacer omission. An example embodiment of the present disclosure includes complementary NMOS and PMOS silicon transistors, wherein the NMOS is provided with inner spacers and the PMOS is not provided with inner spacers.

### FIELD OF THE INVENTION

The present invention is related to semiconductor processing, in particular to the fabrication of nanosheet or nanowire transistors.

### STATE OF THE ART

Nanosheet and nanowire technology has been under development for a number of years, and represents one of the main answers to the limitations of finFET technology in terms of the ongoing scaling requirements of active devices on an integrated circuit chip. In a standalone nanosheet or nanowire transistor, the channel is formed of one or more semiconductor sheets or wires stacked one on top of the other, with the gate dielectric as well as the gate electrode wrapped around the sheets or wires. The term ‘gate all around’ (GAA) is also used for this type of device. The potential of this technology for taking the semiconductor industry towards the so-called 5 nm node and beyond has been well proven.

Nevertheless, further challenges need to be met in terms of improving and finetuning the performance of nanosheet and nanowire transistors. One aspect is related to the use of inner spacers: these are portions of dielectric material arranged adjacent to the inlet and outlet sections of the channel sheets or wires in order to reduce the parasitic capacitance between the gate and the source or drain of the transistor.

The presence of the inner spacers has so far been regarded as an essential requirement of nanosheet or nanowire transistors, regardless of the materials used or the polarity of the charge carriers applied in the device. However, the inclusion of inner spacers represents an added fabrication process complication. Also, the spacers compromise the creation of stress in the channel sheets or wires. Especially this latter negative effect of the inner spacers has not been sufficiently studied. Improved insights in this regard would therefore enable an optimization of the device's performance in general.

### SUMMARY OF THE INVENTION

The invention aims to provide a solution to the problems highlighted above. This aim is achieved by the nanostructure disclosed in the appended claims. A nanostructure according to the invention comprises a pair of nanosheet or nanowire transistors configured to conduct charge by carriers of opposite polarity (such as n and p type carriers), wherein one of the two transistors is provided with inner spacers and the other is not provided with inner spacers. The inventors surprisingly found that depending on the type of charge carrier, the omission of the inner spacers may offer an unexpected improvement in the admittance of the device that outweighs the negative impact of the inner spacer omission. This is the case for example in a Si-channel PMOS nanosheet transistor, whereas in a Si channel NMOS nanosheet transistor, the omission of the inner spacers has a negative effect on the parasitic capacitance that outweighs any benefits of the inner spacer omission.

A preferred embodiment of the invention therefore includes complementary NMOS and PMOS silicon channel nanosheet or nanowire transistors, wherein the NMOS is provided with inner spacers, whereas the PMOS is not provided with inner spacers.

The invention is more particularly related to a nanostructure comprising at least one pair of nanosheet or nanowire field effect transistors configured to conduct charge by charge carriers of opposite polarity (i.e. polarity of charge carriers in one transistor opposite to polarity of charge carriers in the other transistor), each transistor comprising a channel, a gate, a source and a drain, the channel comprising one or more elongate sheets or wires of semiconductor material, the gate comprising a gate dielectric and a gate electrode, and the source and the drain comprising volumes of semiconductor material located on either side of the one or more sheets or wires.

characterized in that
the first of said pair of transistors comprises:
   dielectric inner spacers between the gate electrode and the source,
   dielectric inner spacers between the gate electrode and the drain,
the second of said pair of transistors comprises no dielectric inner spacers between the gate electrode and the source or drain.

In the above, the gate dielectric is preferably a thin stack of dielectric layers that separates the channel sheets or wires from the gate electrode and that is also present between the gate electrode and the source and drain. An ‘inner spacer’ is defined as a portion of dielectric material that separates the gate electrode from the source or drain, in addition to the gate dielectric, and having a thickness (measured in the direction perpendicular to the gate dielectric) that is preferably higher than the thickness of said gate dielectric.

The inner spacers are present on either side of each channel sheet or wire of the ‘one or more sheets or wires’, in the vicinity of the inlet and outlet sections of said sheet or wire (i.e. the sections where the sheets or wires are connected to the source and drain respectively).

The ‘one or more channel sheets or wires’ includes the most common arrangement known as a stack of multiple nanosheets or nanowires arranged one on top of the other. Other configurations are however not excluded. The wording also includes embodiments wherein the channel comprises a single sheet or wire. In a stack of multiple sheets or wires, the inner spacers are situated between the inlet and outlet sections of adjacent channel sheets or wires of the stack and preferably also below the inlet and outlet sections of the bottom sheet or wire of the stack.

In the nanosheet or nanowire transistors of the nanostructure according to the invention, the gate dielectric and the gate electrode are partially or fully wrapped around each of the sheets or wires. In the standalone devices (shown for example in FIGS. 1 to 4), the gate electrode and gate dielectric are fully wrapped around each of the channel sheets or wires. In a forksheet structure, the gate dielectric and gate electrode are partially wrapped around the channel sheets or wires. For example, in a forksheet structure formed of stacked nanosheets (as shown in FIG. 5) the gate dielectric and the gate electrode are wrapped around one lateral side and the upper and lower side of each sheet, while the other lateral side of the sheets is adjacent to a dielectric wall that separates the devices (e.g. complementary NMOS and PMOS transistors) of the forksheet structure.

Preferably, the two transistors of a nanostructure according to the invention are both nanosheet transistors or both nanowire transistors.

According to an embodiment, the pair of transistors are complementary NMOS and PMOS transistors wherein the channel is formed of silicon, and wherein the NMOS transistor is provided with said inner spacers whereas the PMOS transistor is not provided with inner spacers.

According to another embodiment, wherein the pair of transistors are complementary NMOS and PMOS transistors wherein the channel is formed of germanium, and wherein the PMOS transistor is provided with said inner spacers whereas the NMOS transistor is not provided with inner spacers.

In either of the latter two embodiments, a SiGe layer may be provided underneath the transistor that is not provided with inner spacers. Said SiGe layer may comprise dopant elements configured to reduce a leakage current from the source to the drain of the transistor that is not provided with inner spacers.

According to an embodiment, the first transistor comprising inner spacers is further provided with a bottom isolation layer underneath at least the source and drain, whereas no bottom isolation layer is provided underneath the second transistor.

According to an embodiment, the first and second transistor are formed side by side on a semiconductor substrate.

According to an embodiment, the first and second transistor are formed as a forksheet structure, comprising a dielectric wall that separates the first and second transistor.

According to an embodiment, the second transistor is formed on top of the first transistor.

According to an embodiment, the length of the channel sheets or wires of the second transistor (not provided with inner spacers), in the direction from the source to the drain, is the same as the length of the gate electrode.

The invention is equally related to an integrated circuit chip comprising one or more nanostructures according to the invention.

### BRIEF DESCRIPTION OF THE FIGURES

The figures are intended for illustrative purposes and not as on-scale representations of actual devices. Unless specified otherwise, sections along planes labelled B-B and C-C in FIGS. 1a, 2a, etc. are shown respectively in the FIGS. 2b, 3b etc. and 2c, 3c etc. FIGS. 1a and 2a include a legend, indicating the difference between the hatching used for p-doped and n-doped semiconductor material.

FIGS. 1a to 1c illustrate a pair of silicon NMOS and PMOS nanosheet transistors in accordance with an embodiment of the invention.

FIGS. 2a to 2c illustrates another embodiment, wherein the channel length of the PMOS transistor has been shortened compared to the embodiment of FIG. 1.

FIGS. 3a to 3c illustrate an embodiment of a pair of NMOS and PMOS nanosheet transistors according to the invention, wherein a bottom isolation layer is provided underneath the totality of the NMOS transistor.

FIGS. 4a to 4c illustrate an embodiment of a pair of NMOS and PMOS nanosheet transistors according to the invention, wherein a bottom isolation layer is provided underneath the source and drain of the NMOS transistor.

FIG. 5 illustrates a pair of NMOS and PMOS nanosheet transistors according to the invention, arranged in a forksheet nanostructure.

### DETAILED DESCRIPTION OF THE INVENTION

The invention is related to a nanostructure comprising a transistor pair of opposite polarity, wherein both transistors are nanosheet or nanowire) transistors and wherein one of the two is provided with inner spacers while the other is not provided with inner spacers. A nanostructure is defined in the present context as a structure comprising components whose dimensions are on the scale of nanometres or tens of nanometres. The invention is further related to an integrated circuit chip comprising such a nanostructure.

A preferred embodiment is related to complementary Si-channel nanosheet or nanowire transistors, wherein the pair of transistors is respectively an NMOS and a PMOS transistor which are interconnected in a CMOS processing layout, the NMOS being provided with inner spacers, the PMOS not being provided with inner spacers. The idea of applying inner spacers only in one of the two transistors is not self-evident, and would have been expected to be detrimental to the functionality of the interconnected devices.

The presence of the inner spacers may compromise the effect of a source/drain stressor, leaving the channel unstrained, which has a negative influence on the admittance of the channel and thereby on the performance of the overall device, as expressed for example by the delay when the device is turned on or off.

The inventors have performed a comprehensive study of these influences on Si channel NMOS and PMOS nanosheet transistors. The study proves that omitting the inner spacers in a PMOS nanosheet transistor significantly outweighs the negative effects of such an omission, whereas this is not the case in the NMOS nanosheet transistor.

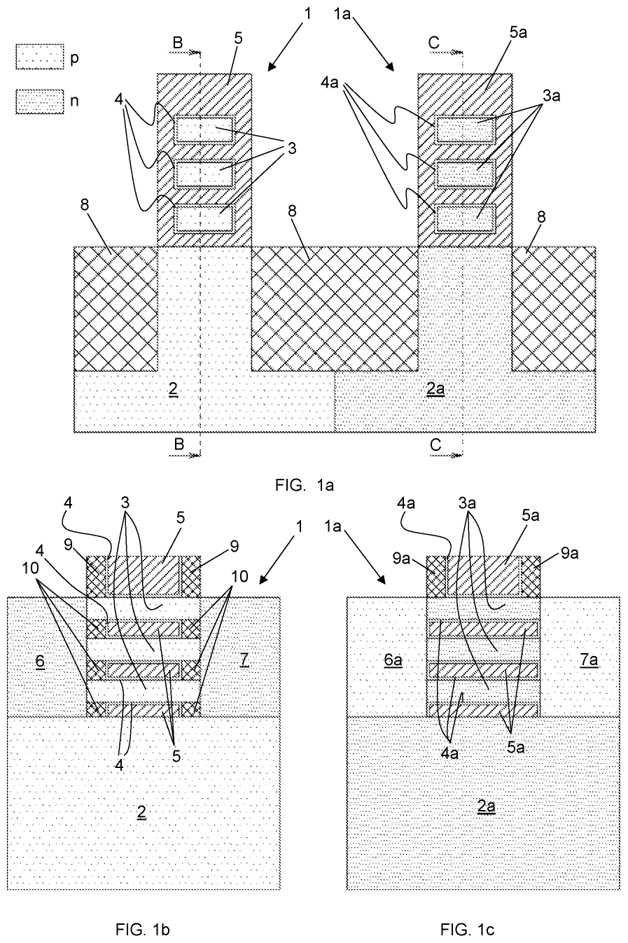

FIGS. 1a to 1c show 2D cross-section views along mutually orthogonal planes of a pair of complementary NMOS and PMOS nanosheet transistors 1 and 1′ placed side by side on a Si substrate, in accordance with the invention, i.e. the NMOS transistor 1 is provided with inner spacers 10 and the PMOS transistor 1′ is not provided with inner spacers. The structure of the NMOS transistor 1 is known to the skilled person. Its main components and its process of fabrication are summarized hereafter.

The NMOS transistor 1 is built on a p-doped portion 2 of a Si substrate, and comprises the following components: a stack of p-doped Si nanosheets 3, a gate dielectric 4, a metal gate electrode 5 wrapped around the Si nanosheets 3, a source 6 and a drain 7. The gate dielectric 4 may be a stack of dielectric layers, such as an interlayer in contact with the Si nanosheets 3 and a high-k dielectric layer on top of the interlayer. The interlayer could be a silicon oxide layer, the high-k layer could be a layer of hafnium oxide. The device is isolated from neighbouring devices by STI (shallow trench isolation) oxide 8. The source 6 and the drain 7 are volumes of epitaxially grown n-doped semiconductor material having appropriate doping profiles in order to enable current to flow through the nanosheet channels 3 when a positive voltage is applied to the gate electrode 5. Outer dielectric spacers 9 are placed on either side of the gate electrode 5. The inner dielectric spacers 10 are present in lateral recesses formed between neighbouring channel sheets 3 and between the bottom channel sheet and the substrate 2. The inner spacers 10 form additional dielectric separations (in addition to the gate dielectric 4), between the gate electrode 5 and the source and drain 6/7.

The outer spacers 9 are a consequence of the replacement gate technique applied for producing the device and which is well known as such, and briefly summarized hereafter. A dummy gate flanked by the outer spacers 9 is formed around a fin-shaped stack of nanosheets comprising the Si channel sheets 3 interspaced with SiGe sacrificial nanosheets. The width of the fin-shaped stack may be in the order of 5 to 40 nm for example. With the dummy gate in place, portions of the fin-shaped stack are removed on either side of the dummy gate, to create cavities that are to be filled with the material of the source and drain by epitaxial growth starting from the lateral surfaces of the Si channel nanosheets 3. In reality several dummy gates may be placed along the length of the fin-shaped structure so as to produce several transistors in a row (only one of these is shown in FIG. 1b). The cavities and the eventual epi-grown source and drains 6/7 are then formed in between two neighbouring dummy gates.

However before this epi-growth step, the SiGe nanosheets are recessed from the sides and the recesses are filled with a dielectric, thereby forming the inner spacers 10. This is then followed by the epitaxial growth of Si, starting from the interfaces of the Si nanosheets and filling up the cavities to thereby form the source and drain areas 6 and 7. The growth may advance from two sides, i.e. also from the channel sheets of neighbouring devices arranged in the length direction of the fin-shaped structures and not shown in FIG. 1b.

The epi-grown areas 6 and 7 may be recessed from the top in order to bring them to the level of the upper Si nanosheet as shown in the drawings, and subjected to dopant implant steps (or the dopant could be added during the epi-growth. After that, the dummy gate is removed (the outer spacers 9 remaining) and the SiGe nanosheets are equally removed, leaving the Si nanosheets 3 suspended between the source and drain 6/7. By atomic layer deposition, the gate dielectric stack 4 is then formed on the exposed surfaces of the Si nanosheets 3 and of the inner and outer spacers 9 and 10, followed by the formation of the gate electrode 5, wrapped around the Si nanosheets 3.

The above-described steps for producing the NMOS transistor 1 may be performed while a hardmask is covering the area where the PMOS transistor 1′ is to be produced. The PMOS 1′ is then produced after the removal of this hardmask and the production of a second hardmask covering the NMOS transistor 1. Alternatively, the fabrication of the PMOS may be done before the fabrication of the NMOS. Corresponding components of the PMOS transistor 1′ are indicated by the same but primed reference numerals 2′, 3′, 4″ etc. The fabrication process for producing the PMOS 1′ is the same as the one for producing the NMOS 1, except for the difference in the doping type of the substrate portion 2′ and the channel sheets 3′ and source and drain areas 6′ and 7′ (alternatively, the channel of both PMOS and NMOS could be formed of undoped Si). Furthermore, the source and drain areas 6′ and 7′ are formed by epitaxial growth of SiGe, not Si, which is related to the creation of stress in the channel sheets (see further). These differences are known as such and are not characteristic for the invention.

The characteristic difference is the fact that the steps required for forming the inner spacers 10 are skipped in the PMOS fabrication process. This means that in the PMOS transistor 1′, the only separation between the gate electrode 5′ and the source and drain 6/7′ is the thin gate dielectric 4′.

As seen in the drawing, the inner spacers 10 of the NMOS transistor 1 are present in addition to the gate dielectric 4, but they are thicker than the gate dielectric 4, and require specific process steps, as described above. In the present context, when a nanosheet or nanowire transistor is said to comprise inner spacers, this refers to dielectric spacers 10 having preferably a higher thickness than the gate dielectric 4. The difference in thickness may be less pronounced than shown in the drawings. For example, the gate dielectric may have a thickness of about 2.5 nm while the inner spacers have a thickness (measured in the direction perpendicular to the gate dielectric) of about 5 nm. Smaller or larger differences or inner spacers having equal thickness to the gate dielectric are not excluded from the scope of the invention. When a nanosheet or nanowire transistor is said to comprise no inner spacers, like the PMOS transistor 1′, this means that only the gate dielectric 4′ separates the gate electrode 5′ from the source and drain 6/7′.

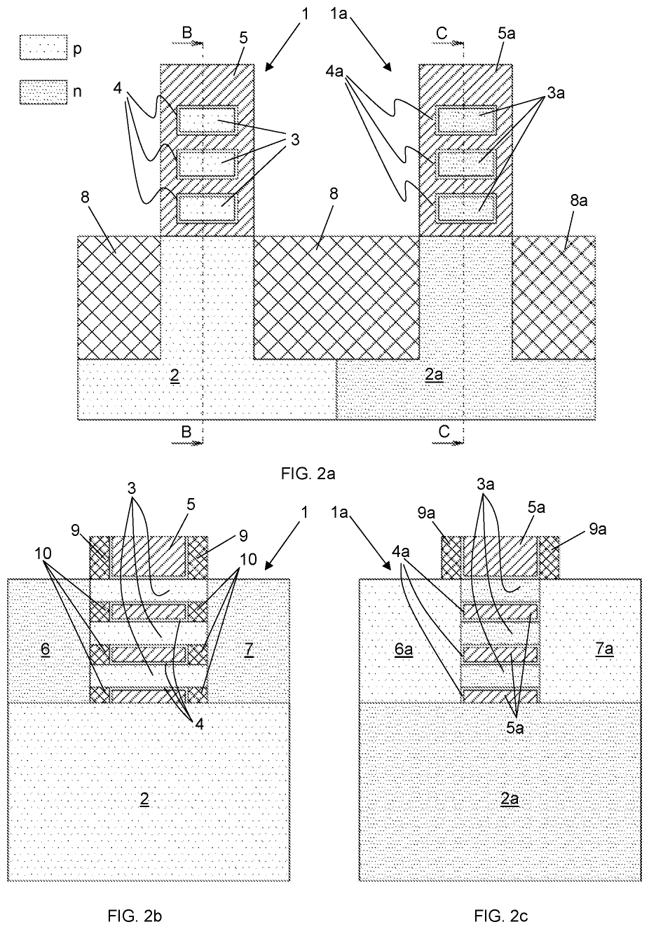

In the embodiment shown in FIGS. 2a to 2c, an additional step is performed in the PMOS fabrication process, to the effect that both the Si nanosheets 3′ and the SiGe sacrificial sheets are recessed to the same degree from the side, so that the length of the channel sheets 3′ corresponds approximately to the length of the gate electrode 5. This is done in order to make the effective gate-length of the device equal to the top (litho/layout defined) gate-length. It is clear however that the SiGe sacrificial sheets have not been recessed relative to the Si nanosheets 3′ and that no internal spacers have been produced. As in the PMOS transistor 1′ shown in FIG. 1a, the only separation between the gate electrode and the source and drain is the gate dielectric stack 4′.

Because the function of the internal spacers 10 is to decrease the parasitic capacitance between the gate and the source/drain areas, it is to be expected that this parasitic capacitance increases significantly in the PMOS transistor 1′ compared to a nanosheet PMOS transistor provided with inner spacers. Indeed, the inventors established from simulations that the parasitic capacitance increases by about 40% both in an NMOS and in PMOS nanosheet transistor, when the inner spacers are omitted. This has a negative effect on the effective admittance of the channel.

On the other hand, it is known that the inner spacers are detrimental to the creation of stress in the channel sheets. Depending on the polarity type of the charge carriers, such stress may be beneficial for the carrier mobility and is generated as a consequence of lattice mismatch between the channel sheets and the epitaxially grown source and drain areas. Due to the inner spacers however, multiple growth fronts appear which leads to non-ideal merging of the epi-growth fronts, thereby diminishing the channel stress. Therefore, omitting the spacers enables to strain the channel sheets to a higher degree. When the channel sheets 3 and 3′ of both the NMOS and the PMOS are formed of Si, the creation of tensile stress is beneficial for the NMOS, whereas the creation of compressive stress is beneficial for the PMOS. The former is difficult to achieve because there are essentially no materials having a lower lattice constant than Si. In a PMOS however, compressive stress can be created by using SiGe or Ge as the epi-grown material for the source and drain, these materials having a higher lattice constant than Si.

Therefore, the impact of omitting the spacers may be expected to be higher in the PMOS 1′ shown in FIGS. 1 and 2 (with SiGe as the source/drain material) compared to the NMOS 1 (with Si as the source/drain material). The inventors have compared the impact of enhanced stress when switching the NMOS and PMOS architectures from the standard structure (with inner spacers) to a structure without inner spacers on the effective channel admittance. Under the influence of enhanced channel stress, the effective admittance of both NMOS and PMOS show an increase of 6% and 82%, respectively. While the impact on NMOS is small, the impact on PMOS is significant and goes beyond the expected difference due to the above-described difference in the source/drain material between NMOS and PMOS. This peculiar disparity was found to be due to an excess of carrier-ion scattering in NMOS compared to PMOS. The size of dopant (boron) acting as scattering centres in PMOS is smaller in comparison to that of NMOS (phosphorus).

Therefore, whereas it would have been expected that any improvement of the effective admittance due to the omission of the inner spacers would be nullified by the increased parasitic capacitance, regardless of the materials used, it was found that this is not always the case, and that for example in the case of the PMOS transistor 1′ illustrated in FIGS. 1 and 2, the enhanced admittance due to the omission of the spacers clearly outweighs the effect of the parasitic capacity increase.

This has been further illustrated by simulations performed by the inventors, calculating the combined delay of transistors 1 and 1′ interconnected in an inverter circuit. It was found that the inverter delay of an inverter circuit built with these devices improves by about 22% compared to the circuit wherein both devices are provided with inner spacers.

In addition, it should be noted that skipping the inner-spacer facilitates a process advantage on the channel-stress front with a ˜35% increase in the stress due to enhanced epi-volume, when the embodiment of FIG. 2 is applied, i.e. the embodiment wherein the effective gate-length of the device is equal to the top (litho/layout defined) gate-length. This effect was not taken into account when calculating the above changes in the device delay. When taking this effect into account, the inverter delay may be expected to decrease by about 28%.

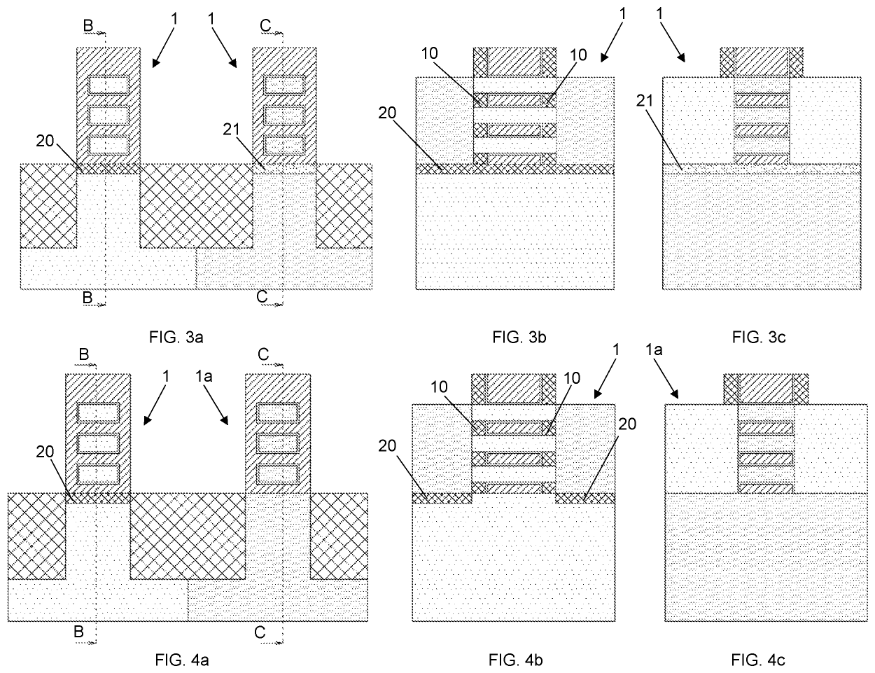

According to preferred embodiments, the pair of transistors is further provided with a bottom isolation layer underneath at least the source 6 and the drain 7 of the NMOS transistor 1, whereas no bottom isolation layer is provided underneath the PMOS transistor 1′. The bottom isolation layer will further reduce the parasitic capacitance of the NMOS transistor. The inclusion of a bottom isolation layer is known as such, as are methods for producing a bottom isolation layer. Two of these known methods and the appearance of the resulting bottom isolation layer are summarized hereafter, and may be applied as such in the method of fabricating the NMOS transistor 1 in a nanostructure according to the invention. In the embodiment illustrated in FIGS. 3a-3c, the bottom isolation layer 20, which could be a Si nitride layer, is formed underneath the entire NMOS device 1, while a SiGe layer 21 is formed underneath the PMOS device 1′. The SiGe layer 21 has a higher Ge content than the sacrificial SiGe nanosheets applied between the Si channel sheets. The sacrificial SiGe nanosheets and the Si nanosheets are formed on this SiGe layer 21 prior to the formation of the fin-shaped nanosheet stacks. The higher Ge content enables etching this layer selectively with respect to the SiGe nanosheets, after the formation of the source and drain 6 and 7, and before removing the SiGe nanosheets themselves. This selective etching is performed on the NMOS, while masking the PMOS, followed by replacing the removed SiGe material of the layer 21 by the bottom isolation layer 20. The SiGe layer 21 thus remains under the PMOS. According to an embodiment, the SiGe layer 21 is doped with n-type dopant elements, which reduces the leakage from source to drain in the PMOS transistor 1′.

According to the embodiment illustrated in FIGS. 4a-4c, the bottom isolation layer 20 is present only underneath the source and drain 6/7 of the NMOS transistor 1. This can be realized by a process which starts from a fin-shaped structure comprising a Si base portion and a stack of SiGe and Si nanosheets, with a dummy gate flanked by external spacers wrapped around the fin shaped structure. The source and drain areas are then recessed by an appropriate lithography and etch process on either side of the external spacers. The etch process continues below the lowermost SiGe nanosheet, creating source and drain recesses in the Si substrate on either side of the external spacers. Then the SiGe nanosheets are recessed from the side, followed by the conformal deposition of a Si nitride layer that fills the source and drain recesses, and the smaller lateral recesses to thereby create the inner spacers 10. The Si nitride layer is thinned until the Si nanosheets are revealed, leaving a bottom isolation layer 20 at the bottom of the source and drain recesses. Then the source and drain is formed by epitaxial deposition, resulting in the NMOS structure shown in FIG. 4b.

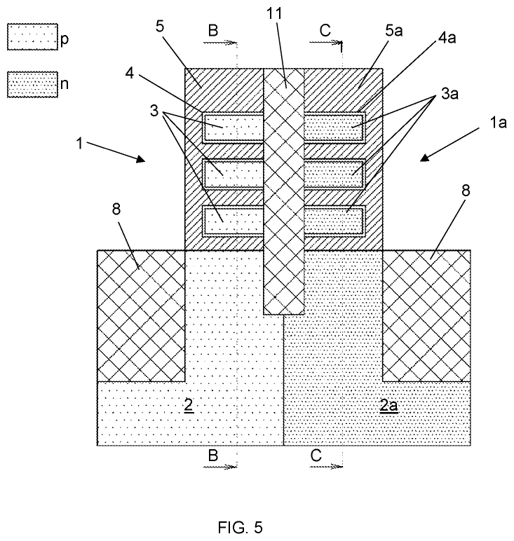

FIG. 5 illustrates another embodiment, according to which the NMOS and PMOS transistors 1 and 1′ are part of a forksheet structure. The different components described above have been indicated in FIG. 5 by the same reference numerals used in FIGS. 1 and 2. The structure comprises a dielectric wall 11 separating the two transistors 1 and 1′. The section views along the planes B-B and C-C indicated in FIG. 5 can be the same as shown in FIGS. 1b and 1c or as in FIGS. 2b and 2c. Fabrication methods for producing a forksheet structure are known as such and therefore not described here in detail. The forksheet structure could also be provided with a bottom isolation layer 20 underneath the NMOS transistor, either underneath the totality of the NMOS (as in FIGS. 3b and 3c or only under the source and drain of the NMOS (as in FIGS. 4b and 4c).

The invention is not limited to transistor pairs 1, 1′ arranged side by side on a substrate, but is also applicable to a so-called CFET structure, wherein the two nanosheet or nanowire transistors are processed one on top of the other. CFET processing is known as such and need not be described here in detail. A CFET nanostructure according to the invention again comprises inner spacers in one of the transistors and not in the other, by omitting the inner spacer fabrication steps in the fabrication process of one of the transistors. A bottom isolation layer may be provided underneath the transistor that comprises inner spacers. For example, a CFET structure according to the invention comprises complementary Si channel nanosheet or nanowire NMOS and PMOS transistors, wherein the PMOS transistor is processed on top of the NMOS transistor, and wherein a bottom isolation layer is provided underneath at least the source and drain of the NMOS transistor, whereas no bottom isolation layer is provided underneath the PMOS transistor.

The invention is not limited to Si-channel devices. When the channel material is germanium, some of the above-described effects may be reversed. Therefore, the invention also includes complementary Ge based NMOS and PMOS transistors, wherein the NMOS is not provided with inner spacers and wherein the PMOS is provided with inner spacers.

In any of the above-described embodiments, the fabrication steps described above are part of so-called front end of line processing and are followed by known steps for producing electrically conductive connections in multiple interconnect layers formed on top of the transistors 1 and 1′, starting with local interconnects which contact the source, drain and gate (sometimes called M0 layer) of the transistors and form interconnections between transistors, for example coupling the complementary transistors 1 and 1′ in an inverter circuit. This is followed by layers M1, M2 etc, in the back end of line process. These interconnect layers and their fabrication methods are well-known in the art and therefore not described here in detail. The result of these processes is a fully operative integrated circuit chip comprising a multitude of transistors and other active semiconductor devices, interconnected in accordance with a given layout.

While the invention has been illustrated and described in detail in the drawings and foregoing description, such illustration and description are to be considered illustrative or exemplary and not restrictive. Other variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. A nanostructure comprising a pair of nanosheet or nanowire field effect transistors configured to conduct charge by charge carriers of opposite polarity, each transistor comprising a respective channel, gate, source, and drain, each channel comprising a respective one or more elongate sheets or wires of semiconductor material, each gate comprising a respective gate dielectric and gate electrode, and each source and each drain comprising respective volumes of semiconductor material located on either side of the one or more sheets or wires, wherein
a first transistor of the pair of transistors comprises:
one or more dielectric inner spacers between the gate electrode of the first transistor and the source of the first transistor, and
one or more dielectric inner spacers between the gate electrode of the first transistor and the drain of the first transistor; and
a second transistor of the pair of transistors comprises no dielectric inner spacers between the gate electrode of the second transistor and the source or drain of the second transistor.

2. The nanostructure according to claim 1, wherein the channel of one of the pair of transistors comprises multiple sheets or multiple wires stacked one on top of the other.

3. The nanostructure according to claim 1, wherein the pair of transistors are complementary NMOS and PMOS transistors, wherein the channels of the pair of transistors are formed of silicon, wherein the first transistor is the NMOS transistor, and wherein the second transistor is the PMOS transistor.

4. The nanostructure according to claim 1, wherein the pair of transistors are complementary NMOS and PMOS transistors, wherein the channels of the pair of transistors are formed of germanium, wherein the first transistor is the PMOS transistor, and wherein the second transistor is the NMOS transistor.

5. The nanostructure according to claim 3, wherein a SiGe layer is provided underneath the second transistor.

6. The nanostructure according to claim 5, wherein the SiGe layer comprises dopant elements configured to reduce a leakage current from the source to the drain of the second transistor.

7. The nanostructure according to claim 1, wherein the first transistor further comprises a bottom isolation layer underneath at least the source and drain of the first transistor, and wherein no bottom isolation layer is provided underneath the second transistor.

8. The nanostructure according to claim 1, wherein the first and second transistors are formed side by side on a semiconductor substrate.

9. The nanostructure according to claim 8, wherein the first and second transistors are formed as a forksheet structure that comprises a dielectric wall that separates the first and second transistors.

10. The nanostructure according to claim 1, wherein the second transistor is formed on top of the first transistor.

11. The nanostructure according to claim 1, wherein a length of the channel sheets or wires of the second transistor, in a direction from the source to the drain of the second transistor, is the same as a length of the gate electrode of the second transistor.

12. An integrated circuit chip comprising:
a nanostructure comprising a pair of nanosheet or nanowire field effect transistors configured to conduct charge by charge carriers of opposite polarity, each transistor comprising a respective channel, gate, source, and drain, each channel comprising a respective one or more elongate sheets or wires of semiconductor material, each gate comprising a respective gate dielectric and a respective gate electrode, and each source and each drain comprising respective volumes of semiconductor material located on either side of the one or more sheets or wires, wherein
the first transistor of the pair of transistors comprises:
one or more dielectric inner spacers between the gate electrode of the first transistor and the source of the first transistor, and
one or more dielectric inner spacers between the gate electrode of the first transistor and the drain of the first transistor; and
the second transistor of the pair of transistors comprises no dielectric inner spacers between the gate electrode of the second transistor and the source or drain of the second transistor.

13. The integrated circuit chip according to claim 12, wherein the channel of each of the transistors comprises multiple sheets or multiple wires stacked one on top of the other.

14. The integrated circuit chip according to claim 12, wherein the at least two pair of transistors are complementary NMOS and PMOS transistors, wherein the channels of the pair of transistors are formed of silicon, wherein the first transistor is the NMOS transistor, and wherein the second transistor is the PMOS transistor.

15. The integrated circuit chip according to claim 12, wherein the pair of transistors are complementary NMOS and PMOS transistors, wherein the channels of the pair of transistors are formed of germanium, wherein the first transistor is the PMOS transistor, and wherein the second transistor is the NMOS transistor.

16. The integrated circuit chip according to claim 12, wherein the pair of transistors are complementary NMOS and PMOS transistors, wherein the channels of the pair of transistors are formed of germanium, wherein the first transistor is the PMOS transistor, and wherein the second transistor is the NMOS transistor.

17. The integrated circuit chip according to claim 12, wherein the first transistor further comprises a bottom isolation layer underneath at least the source and drain of the first transistor, and wherein no bottom isolation layer is provided underneath the second transistor.

18. The integrated circuit chip according to claim 12, wherein the first and second transistor are formed side by side on a semiconductor substrate.

19. The integrated circuit chip nanostructure according to claim 12, wherein the first and second transistor are formed as a forksheet structure that comprises a dielectric wall that separates the first and second transistors.

20. The nanostructure according to claim 4, wherein a SiGe layer is provided underneath the second transistor.
